(19) United States
(12) Patent Application Publication
(10) Pub. No.: US 2013/0140073 A1
(43) Pub. Date: Jun. 6, 2013

(54) ROUTING STRUCTURE FOR CONNECTING SENSOR ELECTRODES USING BLACK ARTWORK ON TOUCH-PANEL GLASS

(71) Applicants: Wei Wang, Shenzhen (CN); William Stacy, San Jose, CA (US)

(72) Inventors: Wei Wang, Shenzhen (CN); William Stacy, San Jose, CA (US)

(73) Assignee: CN INNOVATIONS LIMITED, Hong Kong (CN)

(21) Appl. No.: 13/308,824

(22) Filed: Dec. 1, 2011

(51) Int. Cl. H05K 1/11; H05K 3/00

(52) U.S. Cl. 174/264; 427/555

(57) ABSTRACT

A structure and method is disclosed for a routing structure for connecting the transparent conductive oxide (TCO) electrodes of a touch-sensor panel to a touch controller while providing the requisite cross-over routing. Routing is confined to the border area of a single glass panel where there is no need for transparency. By applying the TCO electrodes to the glass surface, first, and then applying the non-conducting artwork layer above them, there is no need to extend the TCO electrodes above the glass surface and, thereby, subject these thin and brittle electrodes to mechanical stress. Instead, vias are positioned in the artwork then filled with conductive plugs. These provide the connectivity between the TCO electrodes and metal traces above them.

### TECHNICAL FIELD

The present invention relates to a structure and method for connecting touch-panel sensor electrodes to related electronic control subsystems for use in devices featuring touch-screen control.

### BACKGROUND OF THE INVENTION

Many of today's electronic devices, portable devices in particular, feature touch-panel control where a user touches a particular area of a glass screen, or an icon displayed below such a screen, and a subsystem detects that touch and performs a related control function. Touch-panel equipped glass screens are an alternative, for example, to having push-button or keyboard type input devices. In addition to sensing the location of a finger touch, such touch-panel screen controls can also be used to sense motion of the finger touch from one point to another and can respond by, for example, moving the position of an image, drawing a line segment, or increasing or decreasing the magnification of an image. These touch-panels and their control functions are well known in the art.

There are a variety of technologies used in touch-panel equipped systems to determine the position, relative to the screen, of the finger touch. One of the more current and popular technologies uses a mutual-capacitance sensing approach. For mutual-capacitance sensing, using a variety of materials and methods, an array of sensor electrodes are placed onto a transparent glass screen consisting of so-called transmitter and receiver electrodes in close proximity to one another. A voltage is applied to the transmitter electrode and the detector integrates the current at the receiver which is proportional to the mutual capacitance between the transmitter and receiver electrodes. The transmitter and receiver electrodes must remain isolated from one another, that is, the impedance measured between any two electrodes must be very high. The presence of a finger touch will add capacitance to ground lowering the effective mutual capacitance, and indicate where in the spatial array of transmitter and receiver electrodes the lowered mutual capacitance has occurred. That will coincide with where the finger has touched the glass panel. This is prior art and well known to someone practiced in the art.

Because the point where the finger will touch the screen is typically underscored by a displayed image on a display below it, the touch-panel screen and its sensor electrode array must be transparent. Special materials known as transparent conductive oxides (TCOs) are used to make those transparent electrodes, and these are well known in the art.

Some prior art touch sensing systems use multiple glass plates which enables keeping receiver and transmitter electrodes on separate planes and electrically isolated. But today's handheld devices are particularly sensitive to cost, weight and thickness. For all of these reasons, there is most interest in single-glass-plate touch-sensing systems. Ultimately, a single-glass-plate system requires that the sensor electrodes must be routed to a touch controller subsystem and this involves attaching and routing each electrode in such a way that they remain isolated from one another (e.g. a cross-over). Typically, the routing takes place on the periphery of the panel in an area that is opaque so as to hide the metallic routing traces from user view.

Because of the large difference in thickness of the transparent electrodes and the periphery artwork, and the fact that the artwork is laid down before the transparent electrodes, there is a point along the edge of the artwork where the transparent TCO electrodes have to extend up from the glass surface to the surface of the artwork. Indium-Tin-Oxide (ITO) is commonly used as the TCO material. As the ITO transparent electrode material is both very thin and brittle, this region where the transparent electrode extends up to the artwork surface is an area of significant vulnerability and accounts for either a low yield rate or complex process features that add difficulty, time and cost to the touch-panel manufacturing process.

Therefore, a way of routing the transparent electrodes to the touch-panel controller subsystem that would reduce vulnerability, increase yield, and lower overall manufacturing cost would be of great benefit and interest to those practiced in the art.

### BRIEF SUMMARY OF THE INVENTION

It is, therefore, an object of the present invention to reduce the vulnerability to failures of the prior art single-glass approach by using a different method for routing the TCO electrodes that does not expose them to extending above the glass surface thus increasing the likelihood of breaks and manufacturing failures.

In accordance with the disclosed exemplary embodiment, the transparent electrodes are laid down on the glass surface, first, and so remain flat to the glass surface from end to end.

The insulating artwork along the border area of the glass is laid down afterward, and using a system of conducting “vias,” provides the means for routing the electrodes with the requisite cross-over insulating properties (to preserve the electrode isolation), but without subjecting the transparent electrodes to the extension to the artwork surface that is characteristic of the prior art.

With the transparent electrodes, artwork and vias applied to the bottom side of the touch-screen glass, and by using the same artwork color for the conducting via plugs as is used for the insulating artwork, the routing remains hidden from view of the user, as before.

The exemplary embodiment disclosed in this application describes the structure of the insulating artwork, the metallic routing traces, and the vias. It also describes a method for applying the structures and routing the electrodes for connection by the touch-panel controller subsystem.

### BRIEF DESCRIPTIONS OF THE DRAWINGS

FIG. 1 depicts a typical, prior art, approach to implementing touch-control input to an electronic system. As shown, the touch-control system comprises three structures and functions: the touch-screen sensor (101) which functions to determine where a finger has touched the screen by measuring changes in mutual capacitance between transparent conducting transmitter and receiver electrodes; the touch controller (102) which sources voltage to the individual transmitter electrodes and measures the charge by integrating the current at the receiver electrode which is proportional to the mutual capacitance at the receiver electrodes; and the host controller (103) which uses the touch controller information to determine where a user has touched the screen and what actions are to follow.

FIG. 2 depicts a typical, prior art, touch-sensing node comprising a transmitter electrode (201) and its parasitic capacitance to the substrate ground plane (203); and a receiver electrode (202) and its parasitic capacitance to the substrate ground plane (204); and the mutual capacitance that exists between them (205). A voltage is sourced at point 206 of the transmitter electrode, and the current related to mutual capacitance is integrated to find the charge at point 207 on the receiver electrode.

FIG. 3 depicts a portion of a typical, prior art, single-glass touch-screen sensor showing transmitter electrodes (303) and receiver electrodes (304). Typically, other transmitter and receiver electrodes are replicated so as to fill the touch-screen sensor area (301) with discrete transmitter and receiver electrodes that are close to one another but isolated electrically except for mutual capacitance. The portion of the glass (e.g. the border area) where cross-over routing typically occurs (302), shows the leads from each of the electrically isolated electrodes extending into the opaque area where cross-over (305) routing is done using metalized routing traces (306 and 307). Note that the example shows routing traces for the receiving electrodes extending vertically down and crossing-over (305) the metalized routing traces of the transmitting electrodes (306) and the receiving routing traces associated with the receiving electrodes (304). As a result, the metalized routing traces extending downward (307) are all isolated electrically from one another and from the transmitting electrode traces (306).

FIG. 4 depicts the prior art extension (404) of an ITO electrode (403; transmitter or receiver) from the surface of the transparent glass (401) to the surface of the non-conducting opaque artwork (402). The extension, 404, is the primary point of failure during manufacturing due to the brittleness of the ITO material and the stress placed on it in making that extension.

FIG. 5 depicts an exemplary embodiment of the invention. The ITO transparent electrodes (502) are first laid down on the glass surface (501). There is no instance of an extension of the ITO electrodes above the glass as in the prior art. The non-conducting artwork (503) is then laid down and is implemented in such a way that vias (504, cylindrical open channels) are formed in the material between the point where it touches an electrode and where it would touch a metalized routing trace (505 and 506). These vias are then filled with conductive “plugs” (507) whose size and makeup are such that each provides proper connectivity between the ITO electrodes and the metalized routing traces. As such, the requisite routing, connectivity and cross-over is accomplished without having to extend the ITO material off the surface of the glass. Note that the aforementioned “plugs” are implemented with an opaque color that matches that of the non-conducting artwork such that the metalized routing traces, which are not transparent, are nevertheless hidden from view. Note that FIGS. 4 and 5 show the glass plate with its bottom surface on the top and its top surface on the bottom.

### DETAILED DESCRIPTION OF THE INVENTION

The following description covers the structure and methods used for routing the TCO electrodes of a touch screen sensor array, including the requisite cross-over electrode isolation required for proper operation, without extending the TCO electrodes off the glass surface in order to route them to the surface of a non-conducting artwork layer that is thousands of times thicker than the thickness of the TCO electrodes. By so doing, this invention avoids the vulnerability of the extended TCO electrodes leading to higher yields, lower costs, and simpler manufacturing.

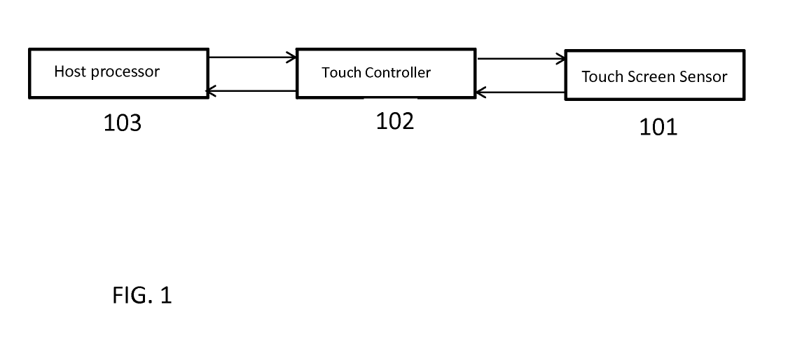

Referring to FIG. 1, the typical touch-screen subsystem comprises a touch-screen sensor (101), a touch controller (102), and a host processor (103). The sensor provides the TCOs in close proximity to one another that permits detecting the presence of a finger tip near one or a plurality of touch sensor nodes. The touch controller sources a voltage to each transmitter electrode and detects the resulting voltage on the receiver electrode. When a finger tip touches the screen above the TCO electrodes, it lowers the mutual capacitance as detected by the sensor and reported by the controller. The controller communicates with the host processor providing it with finger-tip position data, and the host processor uses that data to perform a function or plurality of functions related to the position of the touch, its duration, and/or its path of motion. This is prior art.

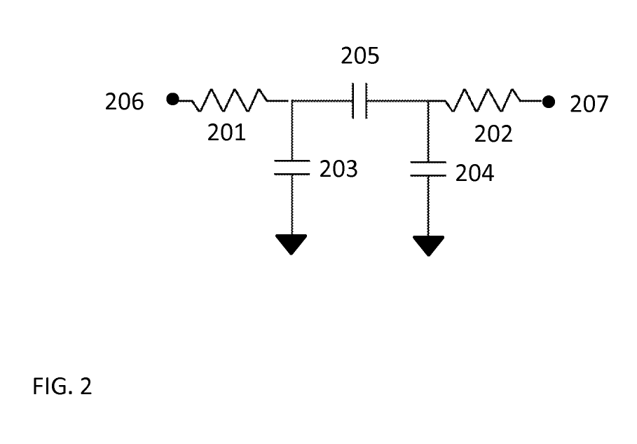

Referring to FIG. 2, the transmitter electrode (201) because of its proximity to the receiver electrode (202) will have a mutual capacitance (205). A voltage sourced at point 206, after charging the parasitic capacitance (203) will produce a voltage on the receiver electrode that will settle after charging parasitic capacitance (204). That voltage measured at point 207 is directly proportional to the mutual capacitance. When a finger tip touches the glass above a sensor node, it lowers the mutual capacitance, and the lower voltage reading indicates the touch that is affecting one or a plurality of sensor nodes below the finger tip. This is prior art.

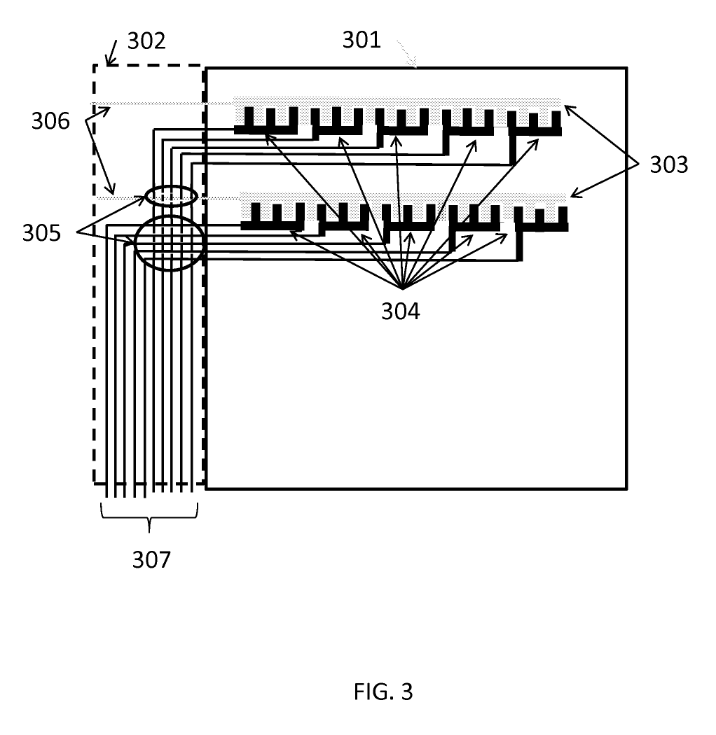

Referring to FIG. 3, a touch screen sensor array of TCO electrodes is typically implemented on a transparent glass (301) with the transmitter and receiver TCO electrodes in close proximity but electrically isolated. The transmitter electrodes are shown as 303 and the receiver electrodes are shown as 304. These TCO electrodes are replicated across the area of the glass to create a spatial array of sensor nodes. The sensor electrodes are routed, in turn, to a touch controller, by the metalized conducting traces (306 and 307), using cross-over techniques (305) to preserve the electrical isolation of the TCO electrodes.

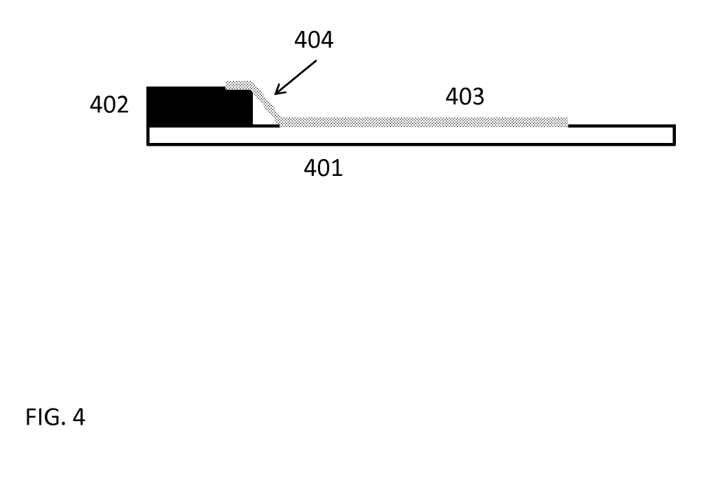

FIG. 4 shows the prior art approach whereby the non-conductive artwork (402) is first applied to glass (401), and then the TCO electrodes are laid down (403). Because of the very significant difference in thickness between the non-conductive artwork layer and the TCO electrodes, the latter is extended above the glass surface to reach the surface of the non-conductive artwork (404). It is this extension that poses the vulnerability to open traces that renders this approach problematic.

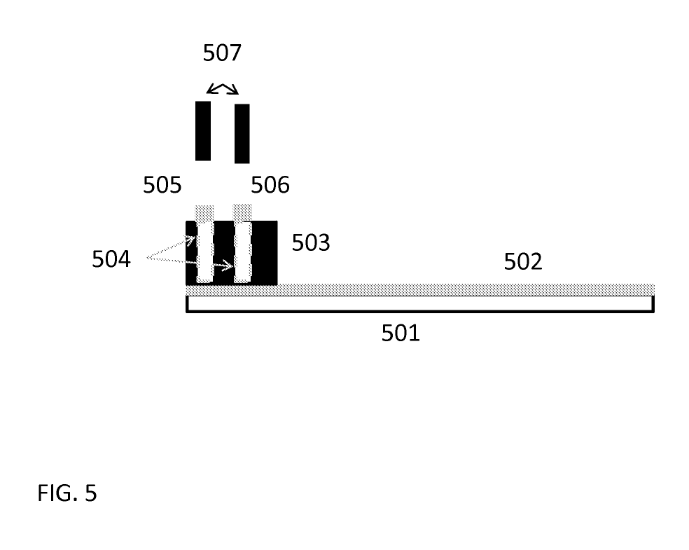

Referring to FIG. 5, this is one embodiment of the disclosed invention. Here, the TCO electrodes are laid down, first (502), across the sensor glass area, (501). The non-conductive artwork (503) is then laid down and patterned with vias (504) above the TCO electrodes that are to be connected to a metalized routing trace above (505 and 506). The vias (504) are cylindrically shaped shafts between the points where the non-conductive layer contacts the TCO electrodes and where it contacts the metalized routing traces (505 and 506). These vias are filled with conductive plugs (507) to provide the conductivity between the individual TCO electrodes and the appropriate routing traces. The conductive plugs are colored with the same coloring as the opaque non-conductive layer. This ensures that when one looks at the top of the glass (shown at the bottom in FIGS. 4 and 5), one will not be able to see the conductive routing traces.

Without requiring any special implementation equipment, this invention accomplishes the cross-over routing required by the touch screen sensor and touch controller, and does so without the extension TCO vulnerability associated with the prior art. There are a variety of methods for laying down the TCO electrodes, a variety of methods for laying down the non-conducting artwork layer, and a variety of methods for laying down the metalized routing traces. There are a variety of methods for patterning the vias in the non-conductive artwork layer. There are a variety of methods for depositing the conductive via plugs in the non-conductive artwork layer. The preferred method uses laser patterning of the TCO electrodes, screen printing of conductive silver, screen printing or inkjet printing of the black conductive via inserts. Alternative methods could use laser patterning of multiple layers of material such as insulator-on-TCO; silver-on-TCO; silver-on-insulator-on-TCO, insulator-on-silver-on-TCO.

The method and structure could consist of a layer of TCO electrodes, a layer of non-conductive artwork in the border area, and a layer of metalized routing traces. It could also use laser patterning of multiple of layers of insulator-conductor-TCO material stacks allowing a narrower border region while accommodating all electrical cross-over routing.

A preferred structure would use a single-glass sensor with all touch-sensor structures on one surface and all cross-over routing done on a narrow border area. An alternative would be to allow cross over structure to be built on extensions of the touch-panel glass assembly, for example, on the surface of extension of panels in the scaffolding area of some touch-module structures.

What is claimed is:

1. A structure for achieving electrical cross-over routing on a single glass panel comprising:
One or a plurality of transparent conductive oxide (TCO) electrodes;
One or a plurality of non-conducting artwork layers;
One or a plurality of metalized routing traces;
One or a plurality of vias in the artwork layers;
One or a plurality of conductive “via plugs.”

2. A structure as in claim 1 further comprising:
The said one or a plurality of TCO electrodes applied to one surface of a glass panel, in close proximity to one another, but isolated electrically from one another;
The said one or a plurality of non-conducting artwork layers applied above the TCO electrodes in a border area of the glass panel;
A pattern of the said one or a plurality of vias in the said one or a plurality of non-conductive artwork layers coinciding with the positions of selected said one or a plurality of TCO electrodes below the lowest layer of said one or a plurality of non-conductive artwork layers.
A pattern of the said one or a plurality of conductive via plugs deposited in the said one or a plurality of vias;
A pattern of the said one or a plurality of metalized routing traces applied to the surface or surfaces of the one or a plurality of non-conductive artwork layers, other than the surface directly above the said one or a plurality of TCO electrodes in the border area of the glass panel, positioned so as to contact the one or a plurality of conductive via plugs.

3. A method for implementing a touch-sensor module and cross-over routing structure on a single glass panel comprising:
Laser patterning of the positioning of said one or a plurality of TCO electrodes;
Deposition of the said one or a plurality of TCO electrodes on the surface of a glass panel in accordance with the said laser patterning;
Screen printing of the said one or a plurality of non-conducting artwork layers including the said one or a plurality of vias positioned above the said one or a plurality of TCO electrodes;
Screen or ink-jet printing of the said one or a plurality of conductive via plugs;
Depositing of the said one or a plurality of conductive via plugs in the said one or a plurality of vias;
Screen or ink-jet printing of the said one or a plurality of metalized routing traces on the surface of the said one or a plurality of non-conductive artwork layers.

4. A method as in claim 3 further comprising:
Color matching the said one or plurality of conductive via plugs to match the color of the said one or a plurality of non-conducting artwork layers;
Depositing of the one or a plurality of color-matched conductive via plugs in the said one or a plurality of vias.
